(19) United States
(12) Patent Application Publication
(10) Pub. No.: US 2026/0308746 A1
(43) Pub. Date: Oct. 8, 2026

(54) PRODUCTIVE COATING PROCESS FOR A STEEL SHEET AND CORRESPONDING EQUIPMENT

(71) Applicant: ArcelorMittal, Luxembourg (LU)

(72) Inventors: Eric GAILLY, Gesves (BE); Nauwfel AMIMI, Petit-Rechain (BE); Eric SILBERBERG, Haltinne (Gesves) (BE); Sergio PACE, Jodoigne (BE); Vincent RUWET, Housse (BE)

(21) Appl. No.: 19/481,575

(22) PCT Filed: Jun. 14, 2024
(86) PCT No.: PCT/IB2024/055843

§ 371 Date: Nov. 5, 2025

(30) Foreign Application Priority Data
Jun. 28, 2023 (WO) PCT/IB2023/056700

(51) Int. Cl. C23C 14/22; C22C 18/00; C23C 14/02; C23C 14/16; C23C 14/24; C23C 14/35; C23C 14/54

(52) U.S. Cl. CPC C23C 14/228; C22C 18/00; C23C 14/021; C23C 14/16; C23C 14/24; C23C 14/35; C23C 14/54

(57) ABSTRACT

20704.1493 substitute specification clean A method for manufacturing a coated steel sheet including the following steps: providing a steel sheet, descaling the steel sheet by acid pickling, feeding thedescaled steel sheet into a pressurized chamber above the atmospheric pressure, the pressurized chamber including an inlet, and being connected via at least one sealing lock to at least one vacuum deposition chamber, depositing a metallic coating layer by vapor deposition at a sonic speed, wherein a gas is blown into the pressurized chamber to keep it at a pressure above atmospheric pressure, the gas being released through the inlet.

### BACKGROUND

Metallic coating of steel sheets is currently performed by hot dipping in a metallic bath. Immediately above the bath, liquid metal is wiped by gas knives to adjust coating thickness. In the case of a galvanizing line, the steel sheet must be heated from 500 to 550° C. to pass in the metal bath while avoiding zinc solidification before the gas knives.

### SUMMARY OF THE INVENTION

The coating thickness range of conventional hot dip coating technology is limited by the process. Bare spots may appear at the lower limit if the wiping pressure is excessive, or liquid metal dripping if the wiping pressure is insufficient at the upper limit of the coating thickness range. Furthermore, it is impossible to hot dip again a coating layer because the metal coating would melt.

Vacuum coating is the deposition of a source material, for example, from the crucible of a vacuum evaporator, on a substrate to form germs (nucleation), which gradually develop (growth) and result in an ordered coating layer. Vacuum coating process is not limited regarding the thickness of the coating deposited. Vacuum deposition can be performed by several successive steps to increase the coating thickness.

When coating by vacuum deposition, heating the steel close to the metal bath temperature is not needed anymore. This allows significant energy and CO2 emissions savings compared to hot dip coating.

It is known from the prior art to coat a cold rolled steel sheet by vacuum deposition. The surface of the cold rolled steel needs to be cleaned to ensure proper adhesion of the coating. Especially when oil or organic residues remain on the cold rolled steel, the coating adhesion will be impaired and bare spots or cracks may appear.

In recent years, the applications for hot rolled steels are increasing in the fields of automotive and general industry. Hot rolled steels offer applications where high corrosion resistance is needed, for examples chassis parts of automobiles or in agricultural environment. It also offers application where minimal corrosion resistance is needed. In other words, the thickness of the corrosion protection needed for hot rolled steels is wide.

However, in the case of the hot rolled steel, the surface is covered by a mill scale resulting from the contact of hot steel with air at the hot rolling mill. Said scale is composed of iron oxides which are layered. The thickness of the scale is from 0.5 to 8 mm. It is porous and brittle and must be removed prior to coating, else the coating wouldn't adhere to the hot rolled steel.

The patent CN 113846291 discloses a cleaning and coating-plating combined unit for a galvanized steel sheet and a production method of the cleaning and coating-plating combined unit. The plasma cleaning can not only realize the descaling of a hot rolled sheet but also realize the surface cleaning of a cold rolled sheet.

However, cleaning by plasma is slow. It is known to use plasma to remove a thin oxide layer of several nanometer. For removing the hot rolling scale of at least 500 nm, the plasma descaling will last longer. On a continuous process, this will require to slow the line speed below the coating deposition speed. The vacuum chamber must be longer compared to a vacuum chamber only dedicated to coating. The resulting equipment is expensive, and its productivity is limited by the line speed necessary for descaling.

A simple and productive process to perform the vacuum coating of both hot rolled and cold rolled steel by is therefore needed with the corresponding equipment.

The present invention provides a method for manufacturing a coated steel sheet including the following steps:
Providing a steel sheet (10),
Descaling said steel sheet by acid pickling,
Feeding said descaled steel sheet into a pressurized chamber (3) above the atmospheric pressure, said pressurized chamber comprising an inlet (2), and being connected via at least one sealing lock (20) to at least one vacuum deposition chamber (4),
Depositing a metallic coating layer by vapor deposition at a sonic speed,
   wherein a gas is blown into the pressurized chamber (3) to keep it at a pressure above atmospheric pressure, said gas being released through the inlet (2).

A second object of the present invention is to provide an equipment able to produce a coated steel sheet by vacuum deposition.

The present invention also provides an equipment for the manufacturing of a coated steel sheet comprising the following units through which the steel sheet is successively driven:
A pickling unit (1) allowing the removal of scale on the surface of said steel,
A pressurized chamber (3) having an inlet (2) and being connected to a sealing lock (20),
At least one jet vacuum deposition chamber (4),
   said equipment comprising means for blowing a gas in the chamber (3) to keep it above atmospheric pressure, said gas being released outside the pressurized chamber through the inlet (2).

A third object of the present invention is to provide a coated hot rolled steel sheet.

The present invention also provides a metallic coated hot rolled steel sheet, comprising successively:
A hot rolled steel sheet,
An oxide layer in contact with said sheet having a thickness from 3 to 60 nm and being mainly composed of iron oxides,
A metallic coating having a thickness from 2.0 to 75.0 μm per side.

### BRIEF DESCRIPTION OF THE DRAWINGS

FIG. 1 shows equipment according to the present invention.

### DETAILED DECRIPTION

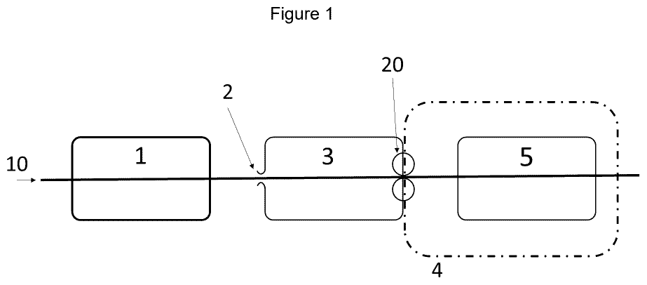

The invention will now be described in detail with reference to FIG. 1 showing equipment according to the present invention.

A first object of the invention is achieved by a method for manufacturing a steel sheet comprising the following steps:
a. Providing a steel sheet 10,
b. Descaling said steel sheet by acid pickling in pickling unit 1,
c. Feeding said descaled steel sheet into a pressurized chamber 3 above the atmospheric pressure, said pressurized chamber comprising an inlet 2, and being connected via at least one sealing lock 20 to at least one vacuum deposition chamber 4,
d. Depositing a metallic coating layer by vapor deposition at sonic speed,
   wherein a gas is blown into the pressurized chamber 3 to keep it at a pressure above atmospheric pressure, said gas being released through the inlet 2.

Preferably, the steel sheet used in the present invention is a hot rolled steel sheet. This means that the steel sheet in steps a. and b. has been hot rolled but has not been cold rolled. The steel sheet of steps a. and b. has a thickness from 1.5 to 30.0 mm, preferably from 1.5 to 20 mm, advantageously from 1.5 to 10.0 mm. For certain applications, hot rolled steel sheets have a thickness from 1.5 to 5.0 mm. Specific hot rolled steel sheets have a thickness from 2.0 to 4.0 mm.

According to the present invention, the descaling at step b) occurs by acid pickling, preferably at a temperature from 60 to 90° C. Acid pickling produces emissions of corrosive acidic vapor and droplets. Such vapor or droplets are highly corrosive. If they penetrate the vacuum chamber, they will deteriorate the equipment in chamber. The acid pickling step can include a rinsing and a drying sub-step. However, this may not be sufficient to prevent acidic vapor or even droplets to be sucked by the low pressure of the vacuum chamber 5. The inventors have found that the pressurized chamber solves this issue.

After descaling by acid pickling, the steel sheet may be shortly exposed to air when transported to the vacuum deposition chamber. When the pickled surface is exposed to air, it becomes immediately oxidized by the oxygen of the atmosphere. A resulting oxide is formed on the surface. It is composed of the elements comprised in the steel sheet. It comprises more than 50 wt % of iron oxides. For example, it can also include aluminum oxides as well as magnesium oxides, depending on the chemical composition of the steel. The thickness of this layer of metal oxides is from 3 to 60 nanometers, more usually from 3 to 20 nm. The thickness of said oxide layer is usually measured by mean of Auger electron spectroscopy.

The steel sheet enters the pressurized chamber through the inlet 2, which acts as a neck having closer walls than the chamber itself and forms a narrow passage. The steel sheet leaves the pressurized chamber through the sealing lock 20.

Preferably, a gas is blown into the pressurized chamber 3 to keep it at a pressure above atmospheric pressure, said gas being released through the inlet 2.

The gas can be blown by any means. For example, the volume of the pressurized chamber can be continuously filled by a fan blowing gas into the pressurized chamber.

Preferably, the pressure in the pressurized chamber is continuously monitored by adjusting the gas flow rate blown in said chamber according to said monitored pressure.

A person ordinary skilled in the art will be able to determine the value of the gas flow rate according to his knowledge. In a preferred embodiment, the flow rate filling the pressurized chamber is from 500 to 15 000 Nm³/h. Preferably, said flow rate is of more than 2 000 Nm³/h, advantageously more than 5 000 or even 10 000 Nm³/h.

Nm³ means normal cubic meter. 1 Nm³ is the amount of gas which, when dry, occupies 1 m³ at a temperature of 0° C. and at an absolute pressure of 101.3 kPa. Nm³/h is a unit for volumetric flow rate of gas at a temperature of 0° C. and pressure of 101.3 kPa, expressed in m³/h.

In a preferred embodiment, the pressurized chamber of step c) has a pressure from 10 to 20 000 Pa above the atmospheric pressure or even better a pressure from 1 000 to 15 000 Pa or from 5 000 to 15 000 Pa above the atmospheric pressure.

If the pressure in the pressurized chamber is less than 10 Pa above the atmospheric pressure, air containing acidic droplets will flow in the vacuum chamber.

If the pressure is more 20 000 Pa above the atmospheric pressure, the sealing lock 20 may not be tight enough and the vacuum may be broken in the vacuum chamber.

Preferably, the pressure in the pressurized chamber is more than 2 000 Pa over the atmospheric pressure, advantageously more than 4 000 Pa, or even more than 6 000 Pa.

In a preferred embodiment, the pressurized chamber is filled with inert gas, for example argon.

In another preferred embodiment, the pressurized chamber is filled with filtered and dried air sucked outside a building that houses said pressurized chamber. Outside air is filtered to remove impurities and dried to remove moisture.

After leaving the pressurized chamber, the steel sheet is transported towards the vacuum chamber. This may occur for example by multistage differential sealing locks which introduce the steel sheet progressively into lower pressure.

Optionally, a primer layer having a thickness from 2 to 15 nm is applied under vacuum on the steel sheet to improve adhesion of the coating. This primer layer is made of metal. It can be applied on the steel sheet by any mean. For example, it is applied by magnetron sputtering.

Optionally, the primer layer consists of stainless steel containing from 10 to 13% by weight nickel, from 16 to 18% by weight chromium, the remainder being iron and potential impurities resulting from the fabrication process.

In a preferred embodiment, the primer layer contains at least 8% by weight nickel and at least 10% by weight chromium, the rest being iron and impurities resulting from the fabrication process.

Optionally, the steel sheet is heated in the vacuum chamber at a temperature from 80 to 200° C., preferably of more than 100° C. and less than 150° C., and advantageously from 120 to 140 °C. This ensures better compacity of the deposited layer.

Optional heating can be carried out by any means, for example by induction. In a preferred embodiment, the inductor to heat the steel sheet can be placed outside the vacuum chamber.

In the vacuum chamber, the metallic coating is applied on the steel sheet by JVD (Jet Vapor Deposition).

The JVD method is a vacuum deposition method in which metal vapor is generated by inductively heating a crucible. Said crucible contains a bath of the coating metal in a vacuum enclosure. The steam escapes from the crucible via a conduct that transports it to an ejector comprising an exit orifice. Said orifice is calibrated, to form a jet at the speed of sound directed at the surface of the substrate to be coated.

The coating layer is applied by jet vapor deposition at sonic speed.

In a preferred embodiment, the coating layer applied by vapor deposition in step d) has a thickness from 2.0 to 75.0 μm per side, advantageously from 10.0 to 55.0 μm.

In a preferred embodiment, the installation is equipped with several ejectors. Several layers of coating are formed on top of each other. In this case, the coating is multi-layered. It comprises 2 or more layers, preferably from 2 to 5 layers.

In a monolayer application by one single ejector, the line speed is limited by the targeted thickness. Indeed, the faster the line speed, the thinner the coating layer.

One of the benefits of the multilayer coating application by several ejectors is the possibility to increase the line speed while keeping the same coating thickness. This allows to increase productivity.

For example, a monolayer coating has a thickness from 2.0 to 10.0 μm, preferably from 2.0 to 7.5 μm.

A multilayer coating has a thickness from 10.0 to 75.0 μm, preferably from 10.0 to 55 μm. This way, the coating can be produced at higher line speed than a monolayer coating.

In a preferred embodiment, the metallic coating consists of zinc and residual impurities coming from the manufacturing process up to 0.1 weight %.

In another preferred embodiment, the metallic coating comprises from 0.5 to 40 weight % magnesium, residual impurities coming from the manufacturing process up to 0.1 weight %, the balance being zinc.

In another preferred embodiment, the metallic coating comprises from 0.5 to 20 weight % magnesium, and from 0.5 to 20 weight % aluminum, residual impurities coming from the manufacturing process up to 0.1 weight %, the balance being zinc.

The legend of FIG. 1 showing an equipment according to the invention is as follows:
1: Pickling Unit;
2: Narrow Opening;
3: Pressurized chamber;
20: Sealing lock;
4: Vacuum deposition chamber;
5: Vacuum chamber;
10: Steel sheet.

What is claimed is:

1-15. (canceled)

16. A method for manufacturing a coated steel sheet comprising the following steps:
a. providing a steel sheet;
b. descaling the steel sheet by acid pickling;
c. feeding the descaled steel sheet into a pressurized chamber above the atmospheric pressure, the pressurized chamber including an inlet, and being connected via at least one sealing lock to at least one vacuum deposition chamber; and
d. depositing a metallic coating layer by vapor deposition at a sonic speed,
wherein a gas is blown into the pressurized chamber to keep the pressurized chamber at a pressure above atmospheric pressure, the gas being released through the inlet.

17. The method according to claim 16 wherein the pressurized chamber has a pressure from 10 to 20 000 Pa above the atmospheric pressure.

18. The method according to claim 16 wherein in step d) the metallic coating has a thickness from 2.0 to 75.0 μm per side.

19. The method according to claim 16 wherein a metallic primer layer with a thickness from 2 to 15 nm is deposited on the steel sheet after step c) and before step d).

20. The method according to claim 16 wherein the steel sheet is a hot rolled steel sheet.

21. Equipment for the manufacturing of a coated steel sheet comprising the following units through which the steel sheet is successively driven:
a pickling unit allowing the removal of scale on the surface of the steel;
a pressurized chamber having an inlet and being connected to a sealing lock;
at least one jet vacuum deposition chamber; and
a blower for blowing a gas into the chamber to keep the chamber above atmospheric pressure, the gas being released outside the pressurized chamber through the inlet.

22. The equipment according claim 21 further comprising a monitor for continuously monitoring the pressure inside the pressurized chamber and an adjustor for adjusting the gas flow rate blown in the chamber according to the monitored pressure.

23. The equipment according claim 21 further comprising a depositor for metallic primer deposition by magnetron sputtering after the pressurized chamber and before the vacuum deposition chamber.

24. The equipment according claim 21 wherein the at least one vacuum deposition chambers comprises two or more ejectors.

25. A metallic coated hot rolled steel sheet, comprising successively:
a hot rolled steel sheet;
an oxide layer in contact with the sheet having a thickness from 3 to 60 nm and being mainly composed of iron oxides; and
a metallic coating having a thickness from 2.0 to 75.0 μm per side.

26. The metallic coated hot rolled steel sheet according to claim 25 comprising a metallic primer layer with a thickness from 2 to 15 nm between the oxide layer and the metallic coating.

27. The metallic coated hot rolled steel sheet according to claim 26 wherein the metallic coating is a monolayer coating and has a thickness from 2.0 to 7.5 μm.

28. The metallic coated hot rolled steel sheet according to claim 26 wherein the metallic coating is a multilayer coating and has a thickness from 10.0 to 75 μm.

29. The metallic coated hot rolled steel sheet according to claim 25 wherein the metallic coating consists of zinc and residual impurities coming from the manufacturing process up to 0.1 weight %.

30. The metallic coated hot rolled steel sheet according to claim 25 wherein the metallic coating comprises from 0.5 to 40 weight % magnesium, residual impurities coming from the manufacturing process up to 0.1 weight %, a balance being zinc.
